(19) United States
(12) Patent Application Publication
(10) Pub. No.: US 2026/0304953 A1
(43) Pub. Date: Oct. 1, 2026

(54) DEVICE LEAKAGE AND YIELD FOR CELLS

(71) Applicant: QUALCOMM Incorporated, San Diego, CA (US)

(72) Inventors: Deepika BALU, Bengaluru (IN); Jaseem AHAMMED, San Marcos, CA (US); Hao WANG, San Diego, CA (US); Arun Kumar Kodigenahalli VENKATESWAR, Bangalore (IN); Ashwin SETHURAM, San Clemente, CA (US)

(21) Appl. No.: 19/091,588

(22) Filed: Mar. 26, 2025

(51) Int. Cl. H10D 84/90; H03K 19/20; H10D 89/10

(52) U.S. Cl. CPC H10D 84/966; H03K 19/20; H10D 84/953; H10D 89/10

(57) ABSTRACT

A chip includes gates extending in a first direction, wherein the gates are spaced apart in a second direction perpendicular to the first direction. The chip also includes a diffusion region extending in the second direction, wherein the gates extend across the diffusion region, the gates do not extend across another diffusion region, the diffusion region comprises bridge channels, and each of the bridge channels passes through a respective one of the gates. The chip also includes gate contacts, wherein each of the gate contacts is disposed on a respective one of the gates, and the gate contacts are located on one side of the diffusion region.

### BACKGROUND

### Field

Aspects of the present disclosure relate generally to chip layout, and more particularly, to chip layout for reducing device leakage.

### Background

A chip includes many transistors for performing various functions on the chip. A transistor may include a gate and a diffusion region (also referred to as active (RX), active region, or another term). The diffusion region may include one or more channels (e.g., one or more nanosheets) passing through the gate.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes first gates extending in a first direction, wherein the first gates are spaced apart in a second direction perpendicular to the first direction, a first diffusion region extending in the second direction, wherein the first diffusion region includes first bridge channels, and each of the first bridge channels passes through a respective one of the first gates, and first gate contacts, wherein each of the first gate contacts is disposed on a respective one of the first gates, and the first gate contacts are located on one side of the first diffusion region. The chip also includes second gates extending in the first direction, wherein the second gates are spaced apart in the second direction, and the second gates are aligned with the first gates in the second direction, a second diffusion region extending in the second direction, wherein the second diffusion region includes second bridge channels, and each of the second bridge channels passes through a respective one of the second gates, and second gate contacts, wherein each of the second gate contacts is disposed on a respective one of the second gates, and the second gate contacts are located on one side of the second diffusion region.

A second aspect relates to a chip. The chip includes first gates extending in a first direction, wherein the first gates are spaced apart in a second direction perpendicular to the first direction. The chip also includes a first diffusion region extending in the second direction, wherein the first gates extend across the first diffusion region, the first gates do not extend across another diffusion region, the first diffusion region includes first bridge channels, and each of the first bridge channels passes through a respective one of the first gates. The chip also includes first gate contacts, wherein each of the first gate contacts is disposed on a respective one of the first gates, and the first gate contacts are located on one side of the first diffusion region.

### BRIEF DESCRIPTION OF THE DRAWINGS

FIG. 1 shows a side view of an example of a chip including a transistor and multiple layers according to certain aspects of the present disclosure.

FIG. 2 shows a perspective view of a gate-all-around transistor according to certain aspects of the present disclosure.

FIG. 3 shows a top view of an exemplary structure including two diffusion regions according to certain aspects of the present disclosure.

FIG. 4A shows a top view of an exemplary structure including a single diffusion region according to certain aspects of the present disclosure.

FIG. 4B shows a perspective view of the exemplary structure of FIG. 4A according to certain aspects of the present disclosure.

FIG. 4C shows the perspective view of FIG. 4B in which gates in FIG. 4B are shown in phantom according to certain aspects of the present disclosure.

FIG. 4D shows a comparison of the exemplary structure of FIG. 4A and the exemplary structure of FIG. 3 according to certain aspects of the present disclosure.

FIG. 5A shows a top view of a first portion of an exemplary layout including two structures arranged in rows where each of the structures includes a single diffusion region according to certain aspects of the present disclosure.

FIG. 5B shows a top view of a second portion of the exemplary layout according to certain aspects of the present disclosure.

FIG. 5C shows a cross-sectional view taken along a first cross-section line in FIG. 5A according to certain aspects of the present disclosure.

FIG. 5D shows a cross-sectional view taken along a second cross-section line in FIG. 5A according to certain aspects of the present disclosure.

FIG. 5E shows a cross-sectional view taken along a third cross-section line in FIG. 5A according to certain aspects of the present disclosure.

FIG. 5F shows a cross-sectional view taken along a fourth cross-section line in FIG. 5A according to certain aspects of the present disclosure.

FIG. 5G shows a cross-sectional view taken along a fifth cross-section line in FIG. 5A according to certain aspects of the present disclosure.

FIG. 5H shows a cross-sectional view taken along a sixth cross-section line in FIG. 5A according to certain aspects of the present disclosure.

FIG. 5I shows a cross-sectional view taken along a seventh cross-section line in FIG. 5A according to certain aspects of the present disclosure.

FIG. 5J shows a cross-sectional view taken along an eighth cross-section line in FIG. 5A according to certain aspects of the present disclosure.

FIG. 6A shows a top view of the first portion of the exemplary layout further including signal routing for implementing logic gates according to certain aspects of the present disclosure.

FIG. 6B shows a top view of the second portion of the exemplary layout further including signal routing for implementing logic gates according to certain aspects of the present disclosure.

FIG. 7A shows an exemplary circuit diagram of a first logic gate according to certain aspects of the present disclosure.

FIG. 7B shows an exemplary circuit diagram of a second logic gate according to certain aspects of the present disclosure.

FIG. 7C shows an exemplary circuit diagram of a third logic gate according to certain aspects of the present disclosure.

FIG. 8A shows a top view of the first portion of the exemplary layout further including floating gates according to certain aspects of the present disclosure.

FIG. 8B shows a top view of the second portion of the exemplary layout further including floating gates according to certain aspects of the present disclosure.

### DETAILED DESCRIPTION

[0030]The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

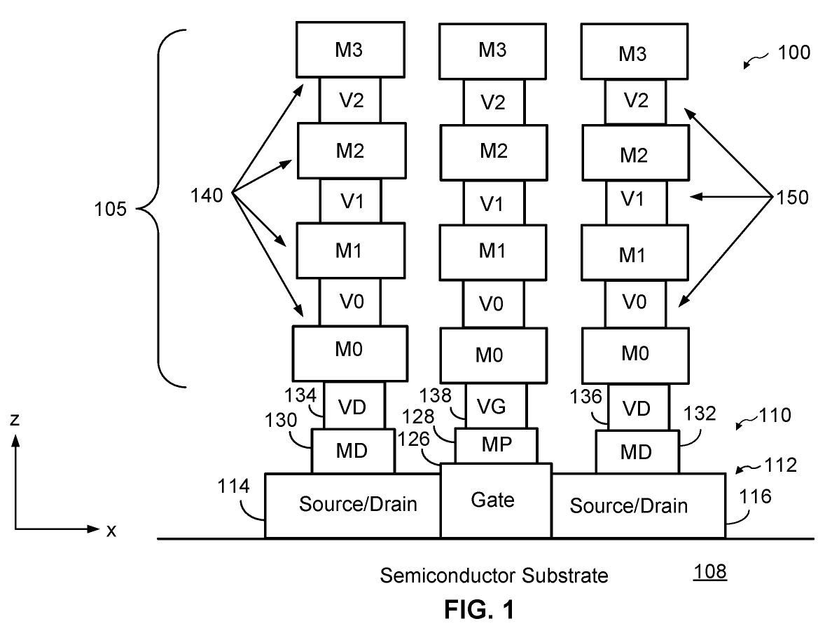

FIG. 1 shows a side view of an example of a chip 100 (e.g., a die) including a transistor 110 and multiple topside layers 105 (also referred to as frontside layers) according to certain aspects. Although one transistor 110 is shown in FIG. 1 for simplicity, it is to be appreciated that the chip 100 includes many transistors. As discussed further below, the transistor 110 may be implemented with a gate-all-around field effect transistor (FET) or another type of transistor. The topside layers 105 are above the transistor 110 in the z direction shown in FIG. 1. The transistor 110 and the topside layers 105 may be formed on a semiconductor substrate 108 (e.g., silicon substrate).

In the example shown in FIG. 1, the transistor 110 includes a diffusion region 112 and a gate 126 on the diffusion region 112. The diffusion region 112 may also be referred to as an active region, active (RX), or another term. The gate 126 may be formed on the diffusion region 112 and include a gate metal (e.g., a high-k metal gate (HKMG)), polysilicon, and/or another gate material.

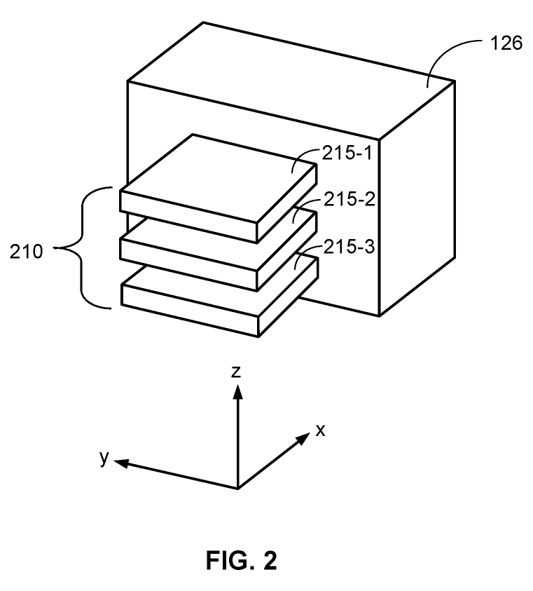

The diffusion region 112 may include a bridge channel extending in the x direction in FIG. 1, in which the x direction is perpendicular to the z direction. In this regard, FIG. 2 shows a perspective view in which the diffusion region 112 includes a bridge channel 210 extending in the x direction through the gate 126 according to certain aspects. As used herein, a “bridge channel” may include a single nanosheet or multiple nanosheets that are stacked vertically. As used herein, “stacked vertically” means stacked in the z direction. A bridge channel including multiple nanosheets that are vertically stacked may also be referred to as a multi-bridge channel (MBC).

In the example shown in FIG. 2, the bridge channel 210 includes multiple nanosheets 215-1 to 215-3 that are vertically stacked. In this example, the gate 126 surrounds each of the nanosheets 215-1 to 215-3 on four sides. Although three nanosheets 215-1 to 215-3 are shown in the example in FIG. 2, it is to be appreciated that the bridge channel 210 may include a single nanosheet or a different number of vertically-stacked nanosheets in other examples.

Returning to FIG. 1, the diffusion region 112 includes a first source/drain 114 on one side of the gate 126 and a second source/drain 116 on the other side of the gate 126. As used herein, the term “source/drain” means a source, a drain, or both a source and a drain. Each of the first source/drain 114 and the second source/drain 116 may include a respective epitaxial (epi) layer and/or another type of material. An epi layer may include epitaxially grown or deposited silicon, a silicon-based material (e.g., silicon-germanium), or any combination thereof. It is to be appreciated that a source/drain may be shared by two transistors in which the source/drain provides a source for each of the transistors, a drain for each of the transistors, or a source for one of the transistors and a drain for the other one of the transistors.

As shown in FIG. 1, the first source/drain 114 and the second source/drain 116 are located on opposite sides of the gate 126. The bridge channel 210 (shown in FIG. 2) may be coupled between the first source/drain 114 and the second source/drain 116, in which the bridge channel 210 controls the conductivity between the first source/drain 114 and the second source/drain 116 based on a voltage applied to the gate 126. The bridge channel 210 may include a single nanosheet or multiple nanosheets (e.g., nanosheets 215-1 to 215-3) passing through the gate 126 (shown in FIG. 2). For example, the bridge channel 210 may include multiple nanosheets to increase the current drive strength of the transistor 110.

In this example, the chip 100 includes a first contact 130 formed on a top surface of the first source/drain 114 and a second contact 132 formed on a top surface of the second source/drain 116. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof. The chip 100 may also include a gate contact 128 formed on the top surface of the gate 126. The gate contact 128 may be referred to as a metal-poly (MP) contact or another term.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1 for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1.

The topside layers 105 also includes vias 150 that provide coupling between the metal layers 140. The vias 150 include vias V0, vias V1, and vias V2. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1, the chip 100 also includes a via 138 disposed between the gate contact 128 and metal layer M0, in which the via 138 couples the gate contact 128 (and hence the gate 126) to metal layer M0. In this example, the chip 100 also includes a via 134 disposed between the first contact 130 and metal layer M0, in which the via 134 couples the first contact 130 to metal layer M0. The chip 100 also includes a via 136 disposed between the second contact 132 and metal layer M0, in which the via 136 couples the second contact 132 to metal layer M0. In the example in FIG. 1, a via (e.g., via 134 or 136) between a source/drain contact and metal layer M0 is labeled VD, and a via (e.g., via 138) between a gate contact and metal layer M0 is labeled VG.

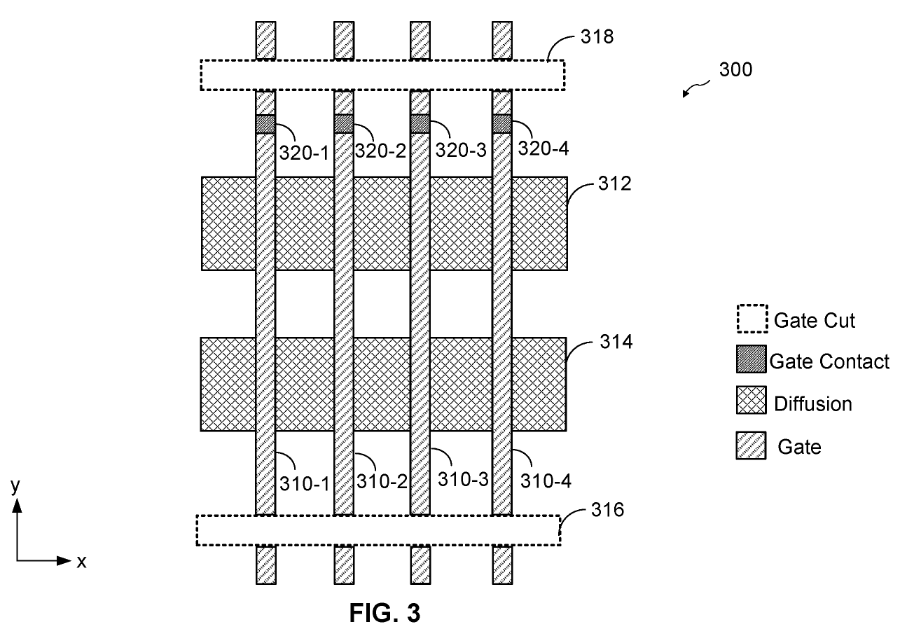

FIG. 3 shows a top view of a layout of an exemplary structure 300 for implementing one or more transistors. The structure includes a first diffusion region 312 and a second diffusion region 314 where each of the diffusion regions 312 and 314 extends in the x direction. The diffusion regions 312 and 314 are spaced apart in the y direction, which is perpendicular to the x direction.

The structure 300 also includes multiple gates 310-1 to 310-4 where each of the gates 310-1 to 310-4 (e.g., an instance of the gate 126) extends in the y direction across the diffusion regions 312 and 314. The gates 310-1 to 310-4 are spaced apart from one another in the x direction (e.g., by a uniform pitch). In the example shown in FIG. 3, the gates 310-1 to 310-4 are cut by gate cuts 316 and 318 (also referred to as cut poly (CT)) extending in the x direction. The diffusion regions 312 and 314 are located between the gate cuts 318 and 316. The gate cuts 316 and 318 separate the gates 310-1 to 310-4 from the gates of other devices (not shown) on the chip 100. In FIG. 3, each of the gate cuts 316 and 318 is represented by a respective dashed rectangle, which indicates the area of the chip 100 that is exposed to an etching process to cut the gates.

Each of the diffusion regions 312 and 314 includes a bridge channel (e.g., an instance of the bridge channel 210 shown in FIG. 2) for each of the gates 310-1 to 310-4. Because there are two diffusion regions 312 and 314 in this example, two bridge channels pass through each of the gates 310-1 to 310-4. In this example, each of the diffusion regions 312 and 314 includes sources/drains that are separated by the gates 310-1 to 310-4. As used herein, “sources/drains” is the plural form of “source/drain.”

The structure also includes gate contacts 320-1 to 320-4 where each of the gate contacts 320-1 to 320-4 (e.g., an instance of the gate contact 128) is disposed on a top surface of a respective one of the gates 310-1 to 310-4. The gate contacts 320-1 to 320-4 are aligned in the y direction and are located between the first diffusion region 312 and the gate cut 318.

The structure 300 may be used to implement one or more transistors. For example, the structure 300 may be used to implement a transistor (e.g., an n-type field effect transistor (NFET) or a p-type field effect transistor (PFET)) having two bridge channels for each of the gates 310-1 to 310-4. In another example, the structure 300 may be used to implement two transistors in which one of the transistors includes the first diffusion region 312, the other one of the transistors includes the second diffusion region 314, and the transistors share the gates 310-1 to 310-4. In this example, each of the transistors has a single bridge channel for each of the gates 310-1 to 310-4. In both of these examples, the structure 300 has a two bridge channel structure in which two bridge channels pass through each of the gates 310-1 to 310-4 (i.e., one bridge channel from the first diffusion region 312 and another bridge channel from the second diffusion region 314).

Ideally, the one or more transistors implemented with the structure 300 conduct no current when the one or more transistors are turned off. However, in practice, the one or more transistors conduct leakage current when turned off, which reduces the power efficiency of the chip 100. The structure 300 shown in FIG. 3 has the following features that contribute to higher leakage current. To begin, the structure 300 does not provide good gate control since the gate contacts 320-1 to 320-4 are located on one side of the first diffusion region 312 and far away from the bridge channels of the second diffusion region 314 located on the other side of the first diffusion region 312. Also, the gate contacts 320-1 to 320-4 are located far from the gate cut 316. As a result, the length of the gates 310-1 to 310-4 between the gate contacts 320-1 to 320-4 and the gate cut 316 is long, which increases gate resistance and leakage current. Accordingly, a structure with lower current leakage is desirable to improve power efficiency.

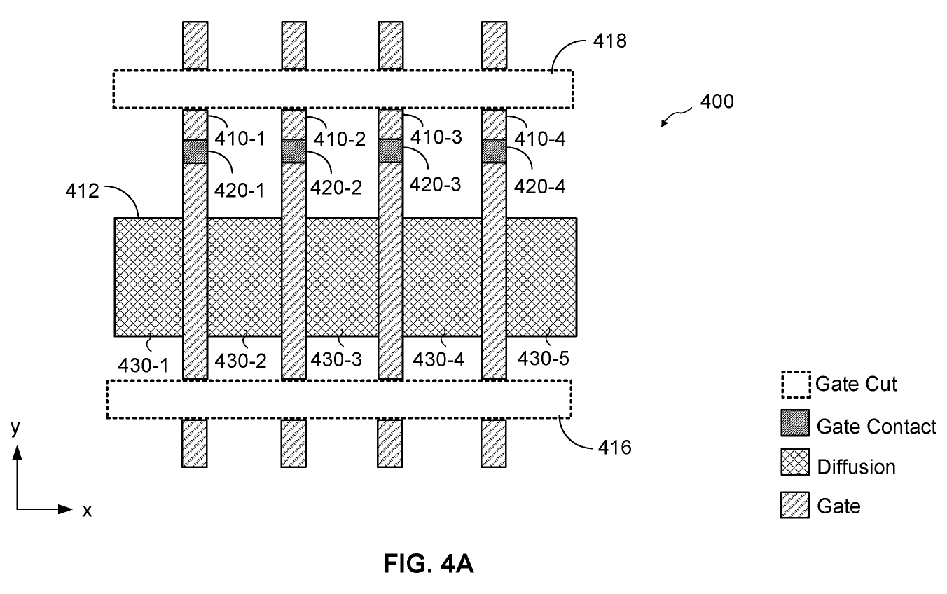

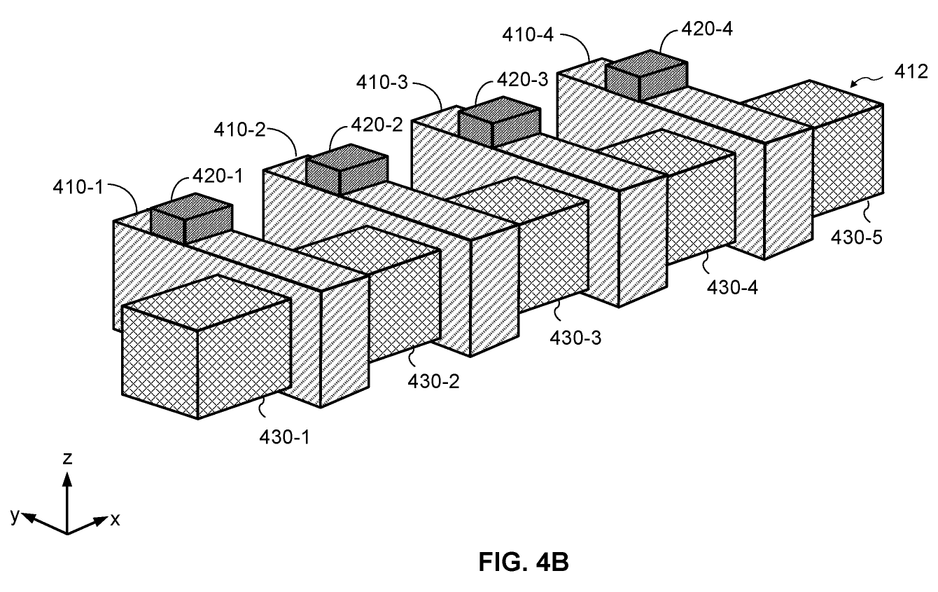

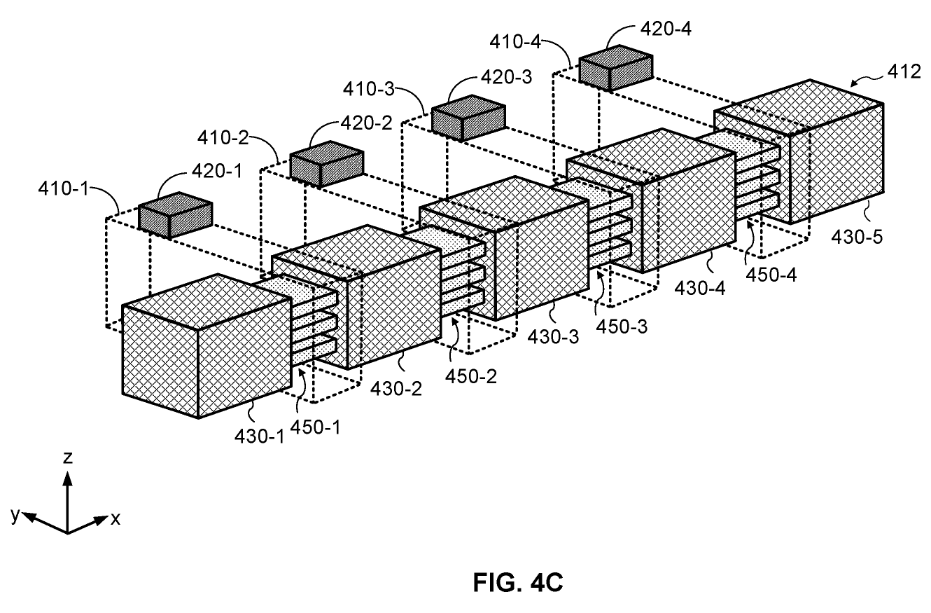

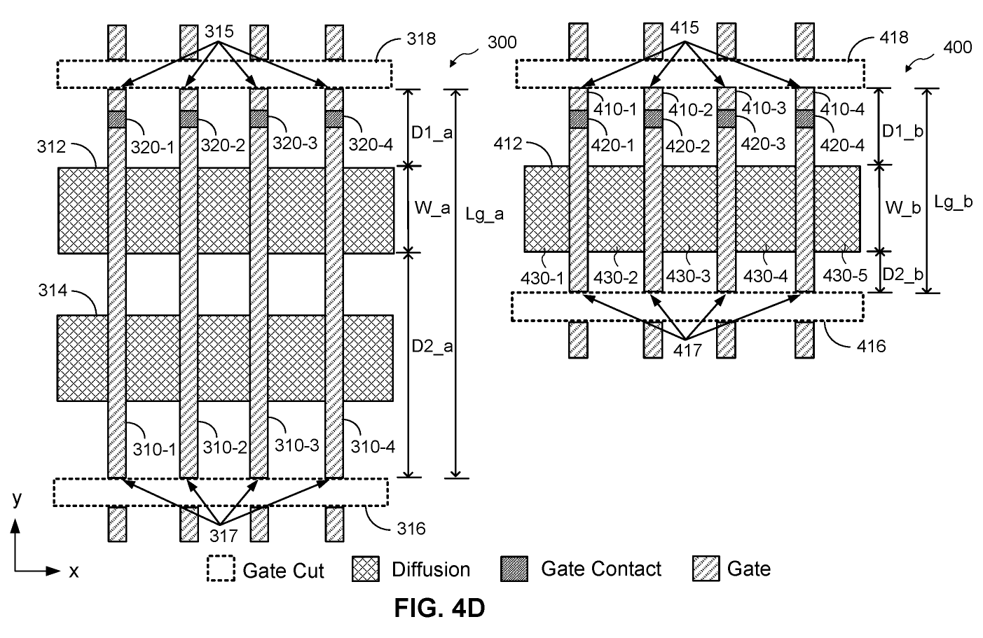

FIG. 4A shows a top view of a layout of an exemplary structure 400 for implementing one or more transistors that significantly reduces leakage current compared with the structure 300 in FIG. 3, as discussed further below. The structure 400 includes a single diffusion region 412 extending in the x direction instead of the two diffusion regions 312 and 314 in the structure 300. As discussed further below, the single diffusion region 412 significantly improves gate control, which reduces leakage current.

The structure 400 also includes multiple gates 410-1 to 410-4 where each of the gates 410-1 to 410-4 (e.g., an instance of the gate 126) extends in the y direction across the single diffusion region 412. As used herein, gates extending across a single diffusion region means that the gates do not extend across another diffusion region. The gates 410-1 to 410-4 are spaced apart (i.e., separated) from one another in the x direction. For example, the gates 410-1 to 410-4 may be spaced apart by a uniform pitch equal to or greater than a minimum gate pitch (also referred to as contacted poly pitch (CPP)) specified by a design rule check (DRC) used to verify that the chip layout satisfies design rules defined for the process technology (also referred to as process node) used to fabricate the chip 100.

In the example shown in FIG. 4A, the gates 410-1 to 410-4 are cut by gate cuts 416 and 418 (also referred to as cut poly (CT)) extending in the x direction. The diffusion region 412 is located between the gate cuts 418 and 416. The gate cuts 416 and 418 separate the gates 410-1 to 410-4 from the gates of other devices (not shown in FIG. 4A) on the chip 100.

The diffusion region 412 includes a bridge channel 450-1 to 450-4 (shown in FIG. 4C) for each of the gates 410-1 to 410-4, as discussed further below. Since the structure 400 includes a single diffusion region 412, one bridge channel passes through each of the gates 410-1 to 410-4. The diffusion region 412 also includes sources/drains 430-1 to 430-5 that are separated by the gates 410-1 to 410-4 (e.g., each of the gates 410-1 to 410-4 is between a respective pair of the sources/drains 430-1 to 430-5). Each of the sources/drains 430-1 to 430-5 may include a respective epitaxial (epi) layer and/or another type of material. As discussed above, an epi layer may include epitaxially grown or deposited silicon, a silicon-based material (e.g., silicon-germanium), or any combination thereof.

The structure 400 also includes gate contacts 420-1 to 420-4 where each of the gate contacts 420-1 to 420-4 (e.g., an instance of the gate contact 128) is disposed on a top surface of a respective one of the gates 410-1 to 410-4. The gate contacts 420-1 to 420-4 are aligned in the y direction. As shown in FIG. 4A, the gate contact 420-1 to 420-4 are located on one side of the diffusion region 412 (i.e., between the diffusion region 412 and the gate cut 418).

FIG. 4B shows a perspective view of the structure 400 and FIG. 4C shows the perspective view of the structure 400 with the gates 410-1 to 410-4 shown in phantom to show the bridge channel 450-1 to 450-4 passing through each of the gates 410-1 to 410-4. In this example, the bridge channel 450-1 passes through the gate 410-1 and is coupled between the source/drain 430-1 and the source/drain 430-2, the bridge channel 450-2 passes through the gate 410-2 and is coupled between the source/drain 430-2 and the source/drain 430-3, the bridge channel 450-3 passes through the gate 410-3 and is coupled between the source/drain 430-3 and the source/drain 430-4, and the bridge channel 450-4 passes through the gate 410-4 and is coupled between the source/drain 430-4 and the source/drain 430-5. In the example shown in FIG. 4C, each bridge channel 450-1 to 450-4 includes multiple nanosheets (e.g., three nanosheets) that are stacked vertically. In this example, each bridge channel 450-1 to 450-4 may also be referred to as an MBC since each bridge channel 450-1 to 450-4 includes multiple nanosheets in this example. However, it is to be appreciated that each bridge channel 450-1 to 450-4 may include a single nanosheet in other implementations.

Since the structure 400 shown in FIGS. 4A, 4B, and 4C includes a single diffusion region 412, one bridge channel 450-1 to 450-4 passes through each of the gates 410-1 to 410-4 instead of the two bridge channels passing through each of the gates 310-1 to 310-4 in the structure 300. As a result, the gate contacts 420-1 to 420-4 are not located far away from the bridge channels of a second diffusion, as is the case in FIG. 3. This significantly improves gate control, which reduces leakage current.

In addition, locating the gate contacts 420-1 to 420-4 on one side of the diffusion region 412 significantly reduces the minimum distance between the diffusion region 412 and the gate cut 416 located on the other side of the diffusion region 412, which further reduces leakage and gate resistance. This is because the distance between the diffusion region 412 and the gate cut 416 does not need to provide additional gate length to accommodate the placement of gate contacts between the diffusion region 412 and the gate cut 416.

Further, the reduced distance between the diffusion region 412 and the gate cut 416 and the omission of a second diffusion region significantly shortens the length of the gates 410-1 to 410-4 in the y direction compared with the length of the gates 310-1 to 310-4 shown in FIG. 3. The shorter gate length significantly reduces gate resistance and leakage current.

In this regard, FIG. 4D shows a comparison between the gate length (labeled “Lg_b”) of the exemplary structure 400 shown in FIG. 4A and the gate length (labeled “Lg_a”) of the exemplary structure 300 shown in FIG. 3. In this example, the gate length Lg_a of the structure 300 includes the distance (labeled “D1_a”) between the first diffusion region 312 and first ends 315 of the gates 310-1 to 310-4 defined by the gate cut 318, the width (labeled “W_a”) of the first diffusion region 312 in the y direction, and the distance (labeled “D2_a”) between the first diffusion region 312 and second ends 317 of the gates 310-1 to 310-4 defined by the gate cut 316, wherein the second ends 317 are opposite the first ends 315. In this example, the distance D2_a is significantly larger than the distance D1_a since the distance D2_a needs to provide sufficient gate length to accommodate the second diffusion region 314 between the first diffusion region 312 and the gate cut 316.

In this example, the gate length Lg_b of the structure 400 includes the distance (labeled “D1_b”) between the diffusion region 412 and first ends 415 of the gates 410-1 to 410-4 defined by the gate cut 418, the width (labeled “W_b”) of the diffusion region 412 in the y direction, and the distance (labeled “D2_b”) between the diffusion region 412 and second ends 417 of the gates 410-1 to 410-4 defined by the gate cut 416, wherein the second ends 417 are opposite the first ends 415, as shown in FIG. 4D. In this example, the distance D2_b between the diffusion region 412 and the gate cut 416 may be significantly shorter than the distance D1_b between the diffusion region 412 and the gate cut 418 (which needs to accommodate the gate contacts 420-1 to 420-4 between the diffusion region 412 and the gate cut 418). For example, since the distance D2_b is not restricted by the placement of gate contacts or a second diffusion between the diffusion region 412 and the gate cut 416, the distance D2_b may be approximately equal to a minimum diffusion-gate cut distance specified by the DRC. As used herein, “minimum diffusion-gate cut distance” is the minimum distance between a diffusion region and a gate cut specified in the DRC of the process technology used to fabricate the chip 100. In certain aspects, the distance D1_b (which needs to accommodate the gate contacts 420-1 to 420-4) may be at least two times longer than the distance D2_b (which may be equal to the minimum diffusion-gate cut distance).

As shown in FIG. 4D, the distance D2_b between the diffusion region 412 and the gate cut 416 may be significantly shorter than the distance D2_a between the first diffusion region 312 and the gate cut 316 since the distance D2_b does not need to accommodate a second diffusion region between the diffusion region 412 and the gate cut 416. This allows the gate length of the structure 400 to be significantly shorter than the gate length of the structure 300, which significantly reduces gate resistance and leakage current.

It is to be appreciated that the structure 400 is not limited to the exemplary orientation shown in FIG. 4A. For example, the structure 400 may be flipped in the y direction in another example. It is also to be appreciated that the structure 400 may be extended in the x direction to include additional gates, addition bridge channels for the additional gates, additional gate contacts for the additional gates, and additional sources/drains, as discussed further below.

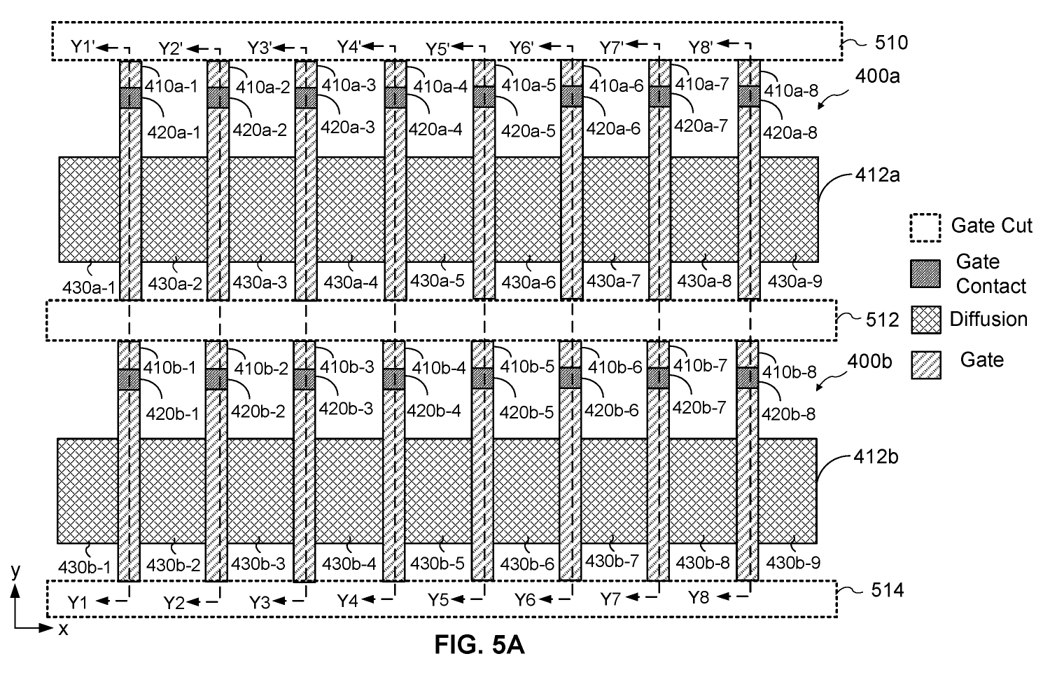

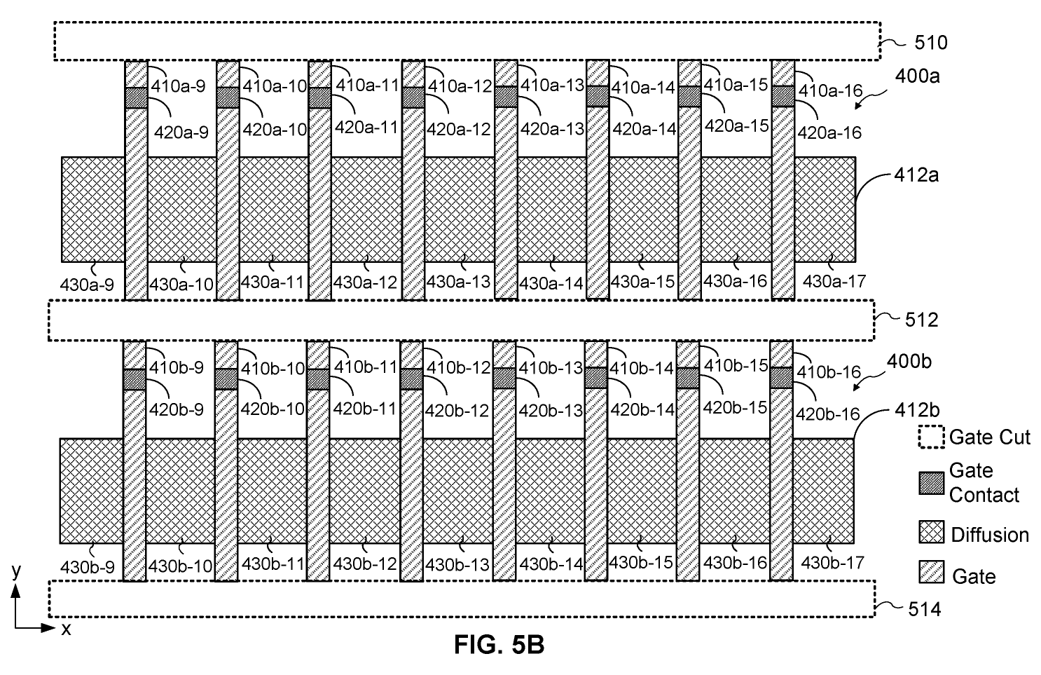

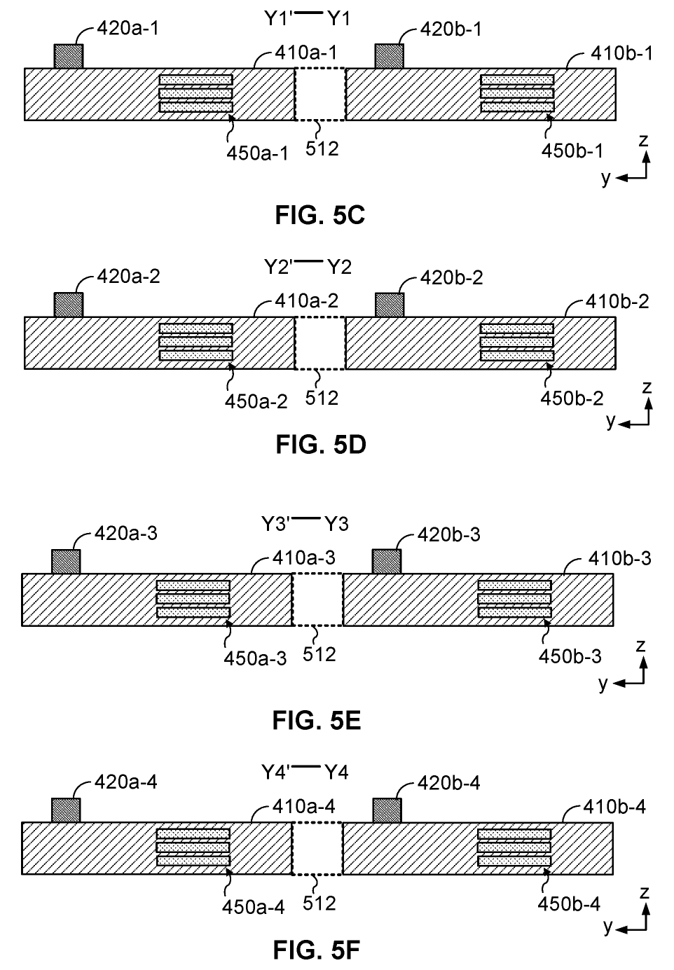

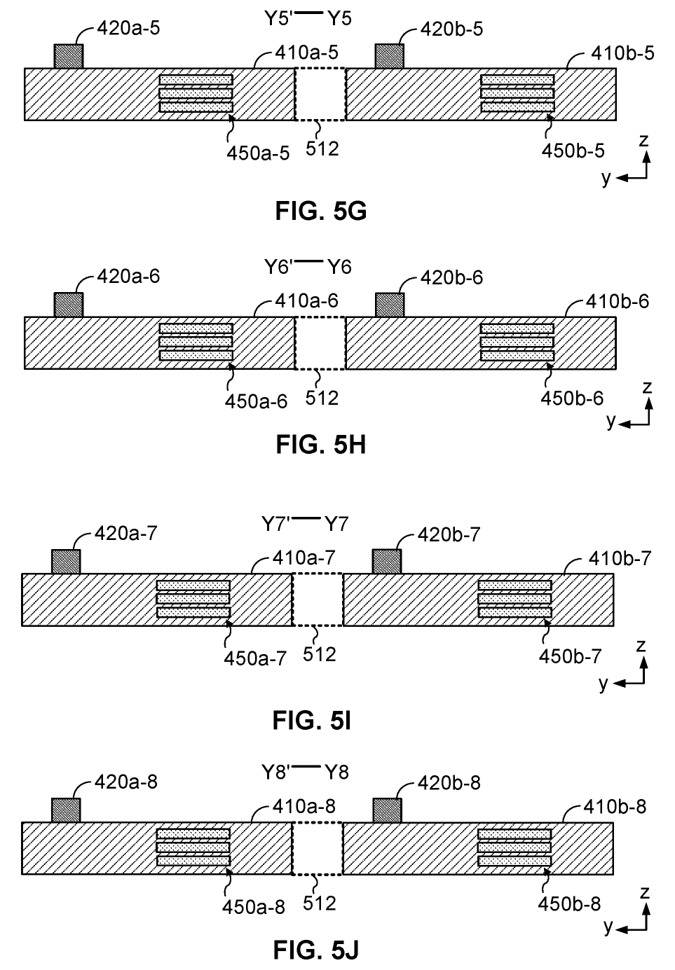

FIGS. 5A and 5B show an exemplary layout including a first structure 400a and a second structure 400b arranged in two rows according to certain aspects. Each of the structures 400a and 400b includes a separate instance of the exemplary structure 400 shown in FIGS. 4A, 4B, 4C, and 4D in which the structure 400 is extended in the x direction. Thus, each of the structures 400a and 400b reduces leakage current for the reasons given above for the structure 400. In FIGS. 5A and 5B, the reference numbers for the elements of the first structure 400a include the letter “a” and the reference numbers for the elements of the second structure 400b include the letter “b”. FIG. 5A shows a first portion of each of the structures 400a and 400b and FIG. 5B shows a second portion of each of the structures 400a and 400b.

In the example shown in FIGS. 5A and 5B, the first structure 400a includes a single diffusion region 412a extending in the x direction. The first structure 400a also includes multiple gates 410a-1 to 410a-16 where each of the gates 410a-1 to 410a-16 (e.g., an instance of the gate 126) extends in the y direction across the diffusion region 412a. The gates 410a-1 to 410a-16 are spaced apart from one another in the x direction (e.g., by a uniform pitch). In this example, the gates 410a-1 to 410a-16 are cut by gate cuts 510 and 512 extending in the x direction. The diffusion region 412a is located between the gate cuts 510 and 512.

The diffusion region 412a includes a bridge channel (e.g., an instance of the bridge channel 210 shown in FIG. 2) for each of the gates 410a-1 to 410a-16. Since the first structure 400a includes a single diffusion region 412a, one bridge channel passes through each of the gates 410a-1 to 410a-16. The diffusion region 412a also includes sources/drains 430a-1 to 430a-17 that are separated by the gates 410a-1 to 410a-16 (i.e., each of the gates 410a-1 to 410a-16 is between a respective pair of the sources/drains 430a-1 to 430a-17). Note that the source/drain 430a-9 is shown in both FIGS. 5A and 5B to better show the spatial relationship between FIGS. 5A and 5B.

The first structure 400a also includes gate contacts 420a-1 to 420a-16 where each of the gate contacts 420a-1 to 420a-16 (e.g., an instance of the gate contact 128) is disposed on a top surface of a respective one of the gates 410a-1 to 410a-16. The gate contacts 420a-1 to 420a-16 are aligned in the y direction. As shown in FIGS. 5A and 5B, the gate contacts 420a-1 to 420a-16 are located on one side of the diffusion region 412a (i.e., between the diffusion region 412a and the gate cut 510).

In the example shown in FIGS. 5A and 5B, the second structure 400b includes a single diffusion region 412b extending in the x direction. The structure 400b also includes multiple gates 410b-1 to 410b-16 where each of the gates 410b-1 to 410b-16 (e.g., an instance of the gate 126) extends in the y direction across the diffusion region 412b. The gates 410b-1 to 410b-16 are spaced apart from one another in the x direction (e.g., by a uniform pitch). In this example, the gates 410b-1 to 410b-16 are cut by gate cuts 512 and 514 extending in the x direction. The diffusion region 412b is located between the gate cuts 512 and 514. In this example, the gate cut 512 separates the gates 410b-1 to 410b-16 of the second structure 400b from the gates 410a-1 to 410a-16 of the first structure 400a in the y direction. Although FIGS. 5A and 5B show one gate cut (i.e., gate cut 512) between the gates 410b-1 to 410b-16 of the second structure 400b and the gates 410a-1 to 410a-16 of the first structure 400a, it is to be appreciated that the present disclosure is not limited to this example. In other implementations, the gates 410b-1 to 410b-16 of the second structure 400b may be separated from the gates 410a-1 to 410a-16 of the first structure 400a by two parallel gate cuts where one of the gate cuts is used to cut the gates 410a-1 to 410a-1 and the other one of the gate cuts is used to cut the gates 410b-1 to 410b-16.

The diffusion region 412b includes a bridge channel (e.g., an instance of the bridge channel 210 shown in FIG. 2) for each of the gates 410b-1 to 410b-16. Since the second structure 400b includes a single diffusion region 412b, one bridge channel passes through each of the gates 410b-1 to 410b-16. The diffusion region 412b also includes sources/drains 430b-1 to 430b-17 that are separated by the gates 410b-1 to 410b-16 (i.e., each of the gates 410b-1 to 410b-16 is between a respective pair of the sources/drains 430b-1 to 430b-17). Note that the source/drain 430b-9 is shown in both FIGS. 5A and 5B to better show the spatial relationship between FIGS. 5A and 5B.

The second structure 400b also includes gate contacts 420b-1 to 420b-16 where each of the gate contacts 420b-1 to 420b-16 (e.g., an instance of the gate contact 128) is disposed on a top surface of a respective one of the gates 410b-1 to 410b-16. The gate contacts 420b-1 to 420b-16 are aligned in the y direction. As shown in FIGS. 5A and 5B, the gate contacts 420b-1 to 420b-16 are located on one side of the diffusion region 412b (i.e., between the diffusion region 412b and the gate cut 512).

It is to be appreciated that the structures 400a and 400b are not limited to the exemplary orientation shown in FIG. 5A and 5B. For example, the first structure 400a may be flipped in the y direction and/or the second structure 400b may be flipped in the y direction in other examples.

In certain aspects, the diffusion region 412a of the first structure 400a is a p-type diffusion region and the diffusion region 412b of the second structure 400b is an n-type diffusion, or vice versa. In these aspects, the first structure 400a may be used for implementing PFETs and the second structure 400b may be used for implementing NFETs, or vice versa.

In the example in FIG. 5A and 5B, the first structure 400a and the second structure 400b are arranged in a first row and a second row, respectively, in which the first structure 400a and the second structure 400b are spaced apart in the y direction. In this example, the gates 410b-1 to 410b-16 of the second structure 400b are aligned with the gates 410a-1 to 410a-16 of the first structure 400a in the x direction. In other words, each of the gates 410b-1 to 410b-16 is aligned with a respective one of the gates 410a-1 to 410a-16 in the x direction. The gates 410b-1 to 410b-16 of the second structure 400b are separated from the gates 410a-1 to 410a-16 of the first structure 400a in the y direction. Also, in this example, the diffusion region 412b is adjacent to the diffusion region 412a in the y direction (i.e., there is no intervening diffusion region between the diffusion regions 412a and 412b in the y direction).

FIGS. 5C to 5J show cross-sectional views of the first portion of the exemplary layout shown in FIG. 5A. More particularly, FIG. 5C shows a cross-sectional view taken along the cross-section line Y1’-Y1 in FIG. 5A, FIG. 5D shows a cross-sectional view taken along the cross-section line Y2’-Y2 in FIG. 5A, FIG. 5E shows a cross-sectional view taken along the cross-section line Y3’-Y3 in FIG. 5A, FIG. 5F shows a cross-sectional view taken along the cross-section line Y4’-Y4 in FIG. 5A, FIG. 5G shows a cross-sectional view taken along the cross-section line Y5’-Y5 in FIG. 5A, FIG. 5H shows a cross-sectional view taken along the cross-section line Y6’-Y6 in FIG. 5A, FIG. 5I shows a cross-sectional view taken along the cross-section line Y7’-Y7 in FIGS. 5A, and 5J shows a cross-sectional view taken along the cross-section line Y8’-Y8 in FIG. 5A. Each of the cross-section lines runs in the y direction and intersects a respective one of the gates 410a-1 to 410a-8 of the first structure 400a and a respective one of the gates 410b-1 to 410b-8 of the second structure 400b.

As shown in FIGS. 5C to 5J, the diffusion region 412a of the first structure 400a includes the bridge channels 450a-1 to 450a-8 in which each of the bridge channels 450a-1 to 450a-8 passing through a respective one of the gates 410a-1 to 410a-8. Each of the bridge channels 450a-1 to 450a-8 is coupled between a respective pair of the sources/drains 430a-1 to 430a-9. More particularly, the bridge channel 450a-1 is coupled between the source/drain 430a-1 and the source/drain 430a-2 (shown in FIG. 5A), the bridge channel 450a-2 is coupled between the source/drain 430a-2 and the source/drain 430a-3 (shown in FIG. 5A), and so forth. In this example, each of the bridge channels 450a-1 to 450a-8 includes multiple (e.g., three) nanosheets that are vertically stacked. However, it is to be appreciated that each of the bridge channels 450a-1 to 450a-8 may include a single nanosheet in other implementations.

As shown in FIGS. 5C to 5J, the diffusion region 412b of the second structure 400b includes the bridge channels 450b-1 to 450b-8 in which each of the bridge channels 450b-1 to 450b-8 passing through a respective one of the gate 410b-1 to 410b-8. Each of the bridge channels 450b-1 to 450b-8 is coupled between a respective pair of the sources/drains 430b-1 to 430b-9. More particularly, the bridge channel 450b-1 is coupled between the source/drain 430b-1 and the source/drain 430b-2 (shown in FIG. 5A), the bridge channel 450b-2 is coupled between the source/drain 430b-2 and the source/drain 430b-3 (shown in FIG. 5A), and so forth. In this example, each of the bridge channels 450b-1 to 450b-8 includes multiple (e.g., three) nanosheets that are vertically stacked. However, it is to be appreciated that each of the bridge channels 450b-1 to 450b-8 may include a single nanosheet in other implementations.

It is to be appreciated that the diffusion region 412a of the first structure 400a also includes bridge channels passing through respective ones of the gates 410a-9 to 410a-16 in FIG. 5B, in which each of the bridge channels may include vertically-stacked nanosheets (i.e., MBC) or a single nanosheet. It is also to be appreciated that the diffusion region 412b of the second structure 400b also includes bridge channels passing through respective ones of the gates 410b-9 to 410b-16 in FIG. 5B, in which each of the bridge channels may include vertically-stacked nanosheets (i.e., MBC) or a single nanosheet.

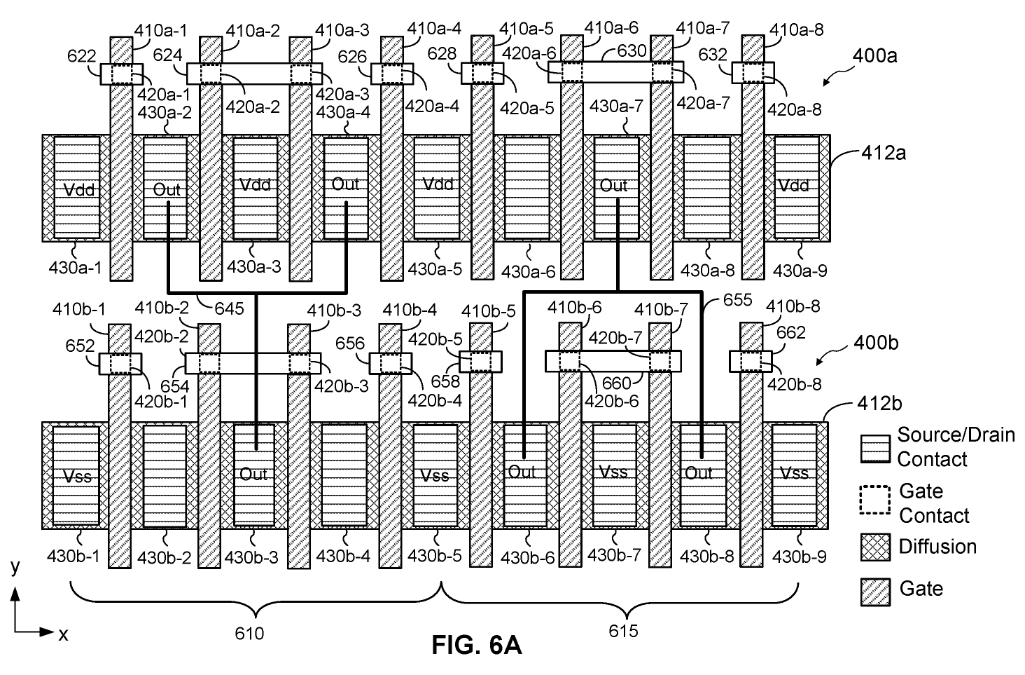

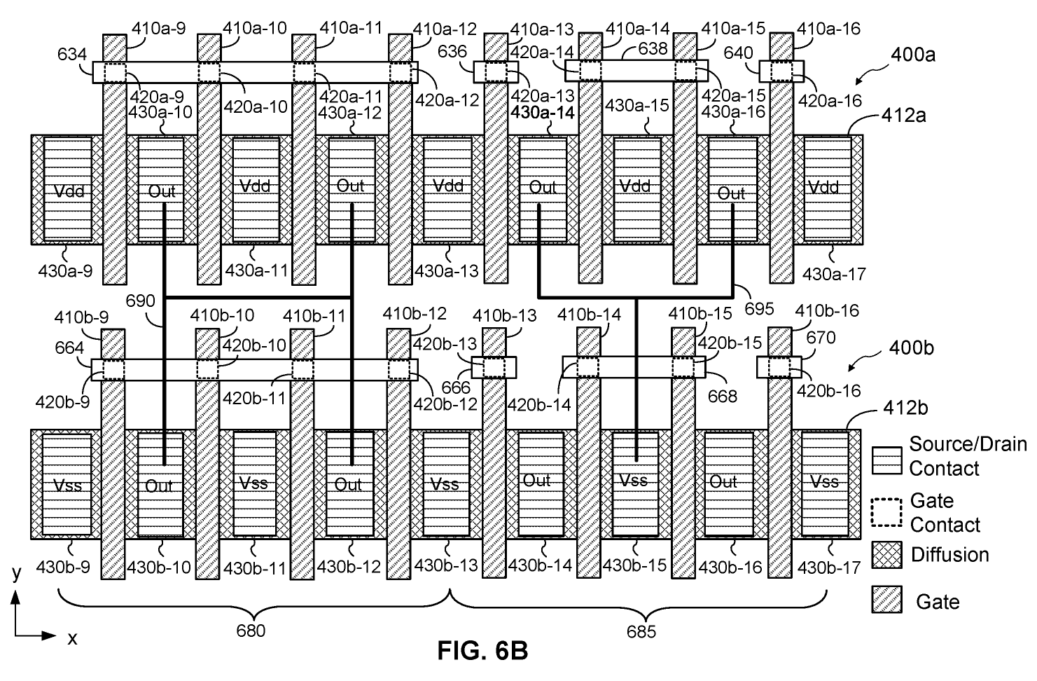

FIGS. 6A and 6B show an example where the first structure 400a and the second structure 400b are used to implement logic gates on the chip 100 according to certain aspects. The logic gates may include a first NAND gate 610, a NOR gate 615, an inverter 680, and a second NAND gate 685. However, it is to be appreciated that the structures 400a and 400b are not limited to these examples.

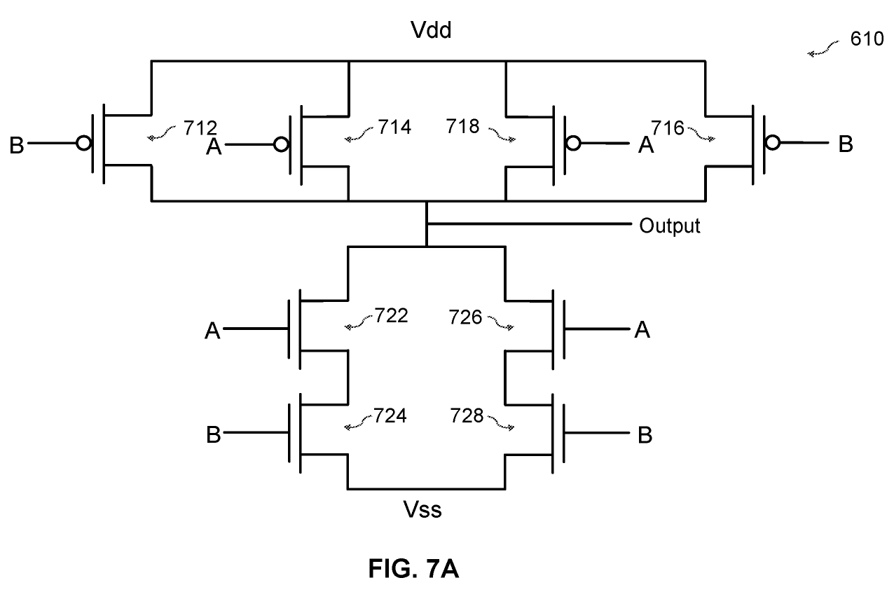

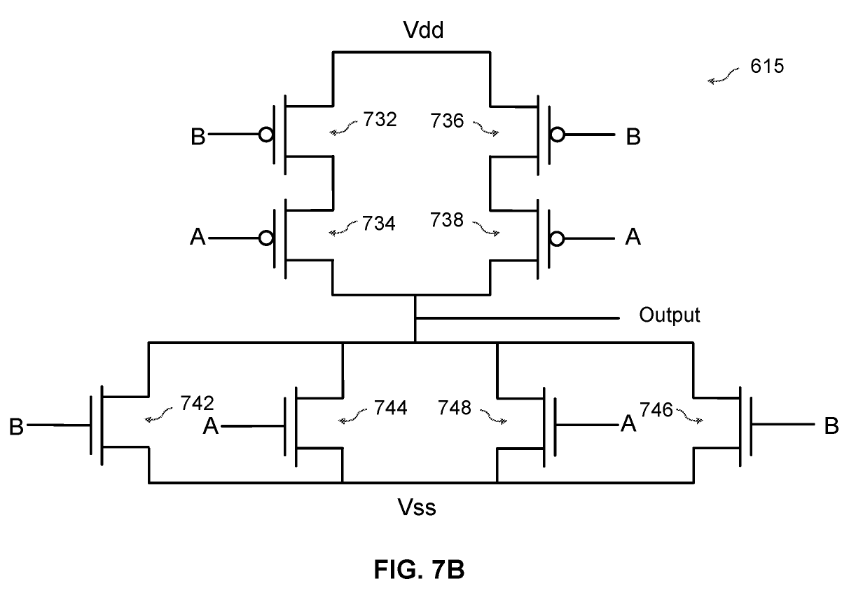

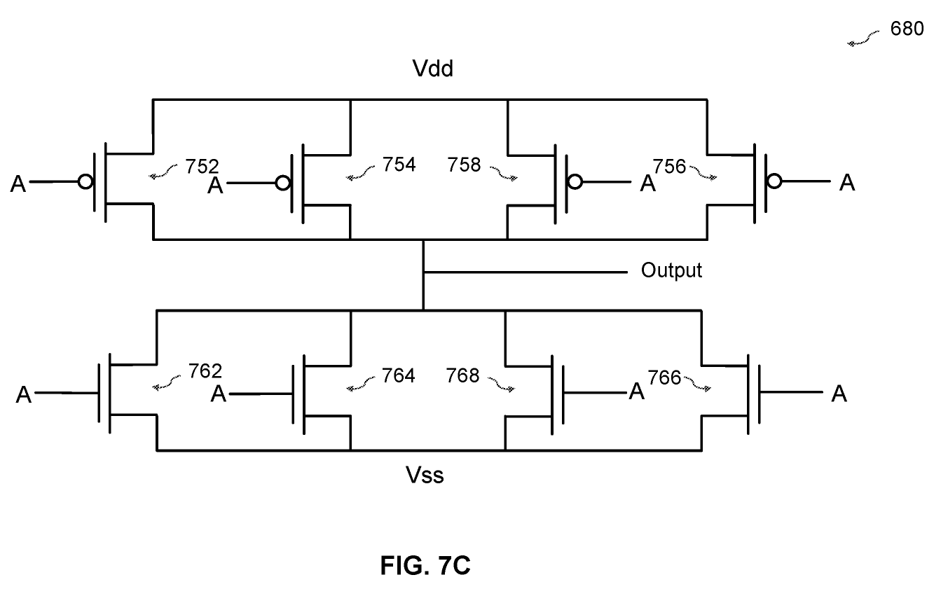

FIG. 7A shows a circuit diagram of the first NAND gate 610. The first NAND gate 610 includes a first PFET 712, a second PFET 714, a third PFET 716, and a fourth PFET 718 coupled in parallel between a supply rail having a supply voltage Vdd and an output of the first NAND gate 610. The gates of the PFETs 714 and 718 are coupled to a first input (labeled “A”) and the gates of the PFETs 712 and 716 are coupled to a second input (labeled “B”). The first NAND gate 610 also includes a first NFET 722, a second NFET 724, a third NFET 726, and a fourth NFET 728. The first NFET 722 and the second NFET 724 are coupled in series between the output and a low rail having a potential of Vss (e.g., ground potential), and the third NFET 726 and the fourth NFET 728 are coupled in series between the output and the low rail. As used herein, a “low rail” is a rail having a potential (e.g., ground potential) that is lower than the supply voltage Vdd. The gates of the NFETs 722 and 726 are coupled to the first input (labeled “A”) and the gates of the NFETs 724 and 728 are coupled to the second input (labeled “B”).

Returning to FIG. 6A, to implement the first NAND gate 610, the layout includes interconnects 622, 624, 626, 652, 654, and 656 formed in metal layer M0 (e.g., using a lithographic and etching process). Each of the interconnects 622, 624, 626, 652, 654, and 656 extends in the x direction. In this example, the interconnect 622 extends above the gate 410a-1, the interconnect 624 extends over the gates 410a-2 and 410a-3, and the interconnect 626 extends over the gate 410a-4. The interconnect 622 is coupled to the gate 410a-1 by the gate contact 420a-1 and a via (e.g., VG in FIG. 1). The interconnect 624 is coupled to the gate 410a-2 by the gate contact 420a-2 and a via (e.g., VG in FIG. 1). The interconnect 624 is also coupled to the gate 410a-3 by the gate contact 420a-3 and a via (e.g., VG in FIG. 1). The interconnect 626 is coupled to the gate 410a-4 by the gate contact 420a-4 and a via (e.g., VG in FIG. 1). In this example, the interconnects 622 and 626 are coupled to the second input (labeled “B” in FIG. 7A) and the interconnect 624 (which is between the interconnects 622 and 626) is coupled to the first input (labeled “A” in FIG. 7A) by signal routing formed in one or more metal layers above metal layer M0.

The interconnect 652 extends above the gate 410b-1, the interconnect 654 extends over the gates 410b-2 and 410b-3, and the interconnect 656 extends over the gate 410b-4. The interconnect 652 is coupled to the gate 410b-1 by the gate contact 420b-1 and a via (e.g., VG in FIG. 1). The interconnect 654 is coupled to the gate 410b-2 by the gate contact 420b-2 and a via (e.g., VG in FIG. 1). The interconnect 654 is also coupled to the gate 410b-3 by the gate contact 420b-3 and a via (e.g., VG in FIG. 1). The interconnect 656 is coupled to the gate 410b-4 by the gate contact 420b-4 and a via (e.g., VG in FIG. 1). In this example, the interconnects 652 and 656 are coupled to the second input (labeled “B” in FIG. 7A) and the interconnect 654 (which is between the interconnects 652 and 656) is coupled to the first input (labeled “A” in FIG. 7A) by signal routing formed in one or more metal layers above metal layer M0.

Also, in this example, the layout includes an interconnect 645 coupled to the source/drain 430a-2, the source/drain 430a-4, and the source/drain 430b-3. Each of the source/drain 430a-2, the source/drain 430a-4, and the source/drain 430b-3 may be coupled to the interconnect 645 by a respective contact (e.g., MD in FIG. 1) and a respective via (e.g., VD in FIG. 1). The interconnect 645 may be formed in metal layer M0 and metal layer M1 (e.g., using a lithographic and etching process) in which the portion of the interconnect 645 formed in metal layer M0 is coupled to the portion of the interconnect 645 formed in metal layer M1 by one of more vias (e.g., V0 in FIG. 1). The interconnect 645 may be coupled to the output of the first NAND gate 610.

The source/drain 430a-1, the source/drain 430a-3, and the source/drain 430a-5 are coupled to the supply rail by respective contacts (e.g., MD in FIG. 1) and vias (e.g., VD in FIG. 1), and the source/drain 430b-1 and the source/drain 430b-5 are coupled to the low rail by respective contacts (e.g., MD in FIG. 1) and vias (e.g., VD in FIG. 1).

In this example, the source/drain 430a-1, the gate 410a-1, and the source/drain 430a-2 provide the source, the gate, and the drain, respectively, of the first PFET 712. The source/drain 430a-3, the gate 410a-2, and the source/drain 430a-2 provide the source, the gate, and the drain, respectively, of the second PFET 714. The source/drain 430a-5, the gate 410a-4, and the source/drain 430a-4 provide the source, the gate, and the drain, respectively, of the third PFET 716. The source/drain 430a-3, the gate 410a-3, and the source/drain 430a-4 provide the source, the gate, and the drain, respectively, of the fourth PFET 718.

Also, the source/drain 430b-3, the gate 410b-2, and the source/drain 430b-2 provide the drain, the gate, and the source, respectively, of the first NFET 722. The source/drain 430b-2, the gate 410b-1, and the source/drain 430b-1 provide the drain, the gate, and the source, respectively, of the second NFET 724. The source/drain 430b-3, the gate 410b-3, and the source/drain 430b-4 provide the drain, the gate, and the source, respectively, of the third NFET 726. The source/drain 430b-4, the gate 410b-4, and the source/drain 430b-5 provide the drain, the gate, and the source, respectively, of the fourth NFET 728.

FIG. 7B shows a circuit diagram of the NOR gate 615. The NOR gate 615 includes a first PFET 732, a second PFET 734, a third PFET 736, and a fourth PFET 738. The first PFET 732 and the second PFET 734 are coupled in series between the supply rail and the output of the NOR gate 615, and the third PFET 736 and the fourth PFET 738 are coupled in series between the supply rail and the output of the NOR gate 615. The gates of the PFETs 734 and 738 are coupled to a first input (labeled “A”) and the gates of the PFETs 732 and 736 are coupled to a second input (labeled “B”). The NOR gate 615 also includes a first NFET 742, a second NFET 744, a third NFET 746, and a fourth NFET 748 coupled in parallel between the output and the low rail. The gates of the NFETs 744 and 748 are coupled to the first input (labeled “A”) and the gates of the NFETs 742 and 746 are coupled to the second input (labeled “B”).

Returning to FIG. 6A, to implement the NOR gate 615, the layout includes interconnects 628, 630, 632, 658, 660, and 662 formed in metal layer M0 (e.g., using a lithographic and etching process) and extending in the x direction. In this example, the interconnect 628 extends above the gate 410a-5, the interconnect 630 extends over the gates 410a-6 and 410a-7, and the interconnect 632 extends over the gate 410a-8. The interconnect 628 is coupled to the gate 410a-5 by the gate contact 420a-5 and a via (e.g., VG in FIG. 1). The interconnect 630 is coupled to the gate 410a-6 by the gate contact 420a-6 and a via (e.g., VG in FIG. 1). The interconnect 630 is also coupled to the gate 410a-7 by the gate contact 420a-7 and a via (e.g., VG in FIG. 1). The interconnect 632 is coupled to the gate 410a-8 by the gate contact 420a-8 and a via (e.g., VG in FIG. 1). In this example, the interconnects 628 and 632 are coupled to the second input (labeled “B” in FIG. 7B) and the interconnect 630 (which is between the interconnects 628 and 632) is coupled to the first input (labeled “A” in FIG. 7B) by signal routing formed in one or more metal layers above metal layer M0.

The interconnect 658 extends above the gate 410b-5, the interconnect 660 extends over the gates 410b-6 and 410b-7, and the interconnect 662 extends over the gate 410b-8. The interconnect 658 is coupled to the gate 410b-5 by the gate contact 420b-5 and a via (e.g., VG in FIG. 1). The interconnect 660 is coupled to the gate 410b-6 by the gate contact 420b-6 and a via (e.g., VG in FIG. 1). The interconnect 660 is also coupled to the gate 410b-7 by the gate contact 420b-7 and a via (e.g., VG in FIG. 1). The interconnect 662 is coupled to the gate 410b-8 by the gate contact 420b-8 and a via (e.g., VG in FIG. 1). In this example, the interconnects 658 and 662 are coupled to the second input (labeled “B” in FIG. 7B) and the interconnect 660 (which is between the interconnects 658 and 662) is coupled to the first input (labeled “A” in FIG. 7B) by signal routing formed in one or more metal layers above metal layer M0.

Also, in this example, the layout includes an interconnect 655 coupled to the source/drain 430a-7, the source/drain 430b-6, and the source/drain 430b-8. Each of the source/drain 430a-7, the source/drain 430b-6, and the source/drain 430b-8 may be coupled to the interconnect 655 by a respective contact (e.g., MD in FIG. 1) and a respective via (e.g., VD in FIG. 1). The interconnect 655 may be formed in metal layer M0 and metal layer M1 (e.g., using a lithographic and etching process) in which the portion of the interconnect 655 formed in metal layer M0 is coupled to the portion of the interconnect 655 formed in metal layer M1 by one of more vias (e.g., V0 in FIG. 1). The interconnect 655 may be coupled to the output of the NOR gate 615.

The source/drain 430a-5 and the source/drain 430a-9 are coupled to the supply rail by respective contacts (e.g., MD in FIG. 1) and vias (e.g., VD in FIG. 1), and the source/drain 430b-5, the source/drain 430b-7, and the source/drain 430b-9 are coupled to the low rail by respective contacts (e.g., MD in FIG. 1) and vias (e.g., VD in FIG. 1). In FIGS. 6A and 6B, the label “VDD” indicates that the corresponding source/drain is coupled to the supply rail and the label “VSS” indicates that the corresponding source/drain is coupled to the low rail (e.g., ground rail). A contact (e.g., MD in FIG. 1) for a source/drain may also be referred to as a source/drain contact.

In this example, the source/drain 430a-5, the gate 410a-5, and the source/drain 430a-6 provide the source, the gate, and the drain, respectively, of the first PFET 732. The source/drain 430a-6, the gate 410a-6, and the source/drain 430a-7 provide the source, the gate, and the drain, respectively, of the second PFET 734. The source/drain 430a-9, the gate 410a-8, and the source/drain 430a-8 provide the source, the gate, and the drain, respectively, of the third PFET 736. The source/drain 430a-8, the gate 410a-7, and the source/drain 430a-7 provide the source, the gate, and the drain, respectively, of the fourth PFET 738.

Also, the source/drain 430b-6, the gate 410b-5, and the source/drain 430b-5 provide the drain, the gate, and the source, respectively, of the first NFET 742. The source/drain 430b-6, the gate 410b-6, and the source/drain 430b-7 provide the drain, the gate, and the source, respectively, of the second NFET 744. The source/drain 430b-8, the gate 410b-8, and the source/drain 430b-9 provide the drain, the gate, and the source, respectively, of the third NFET 746. The source/drain 430b-8, the gate 410b-7, and the source/drain 430b-7 provide the drain, the gate, and the source, respectively, of the fourth NFET 748.

In this example, the source/drain 430a-5 and the source/drain 430b-5 are shared by the first NAND gate 610 and the NOR gate 615. This allows each of the diffusion regions 412a and 412b to be contiguous (i.e., continuous) across the first NAND gate 610 and the NOR gate 615 with no diffusion breaks separating the first NAND gate 610 and the NOR gate 615. The first NAND gate 610 and the NOR gate 615 are able to share a source/drain that is coupled to the supply rail or the low rail. In the example shown in FIG. 6A, the shared source/drain 430a-5 in the diffusion region 412a (which is p-type in this example) is coupled to the supply rail and the shared source/drain 430b-5 in the diffusion region 412b (which is n-type in this example) is coupled to the low rail (e.g., ground rail).

In this example, the first NAND gate 610 is laid out such that the outermost sources/drains 430a-1 and 430a-5 of the first NAND gate 610 in the diffusion region 412a are coupled to the supply rail and the outermost sources/drains 430b-1 and 430b-5 of the first NAND gate 610 in the diffusion region 412b are coupled to the low rail. Also, the NOR gate 615 is laid out such that the outermost sources/drains 430a-5 and 430a-9 of the NOR gate 615 in the diffusion region 412a are coupled to the supply rail and the outermost sources/drains 430b-5 and 430b-9 of the NOR gate 615 in the diffusion region 412b are coupled to the low rail. This layout methodology allows the NOR gate 615 and the first NAND gate 610 to share the source/drain 430a-5 coupled to the supply rail and share the source/drain 430b-5 coupled to the low rail (e.g., ground rail), which allows the diffusion regions 412a and 412b to be continuous across the first NAND gate 610 and the NOR gate 615.

FIG. 7C shows a circuit diagram of the inverter 680. The inverter 680 includes a first PFET 752, a second PFET 754, a third PFET 756, and a fourth PFET 758 coupled in parallel between the supply rail and the output of the inverter 680. The gates of the PFETs 752, 754, 756, and 758 are coupled to an input (labeled “A”) of the inverter 680. The inverter 680 also includes a first NFET 762, a second NFET 764, a third NFET 766, and a fourth NFET 768 coupled in parallel between the output and the low rail. The gates of the NFETs 762, 764, 766, and 768 are coupled to the input (labeled “A”) of the inverter 680.

Returning to FIG. 6B, to implement the inverter 680, the layout includes interconnects 634 and 664 formed in metal layer M0 (e.g., using a lithographic and etching process) and extending in the x direction. In this example, the interconnect 634 extends above the gates 410a-9, 410a-10, 410a-11, and 410a-12 and is coupled to the gates 410a-9, 410a-10, 410a-11, and 410a-12 by the respective gate contacts 420a-9, 420a-10, 420a-11, and 420a-12 and respective vias (e.g., VG in FIG. 1). The interconnect 664 extends above the gates 410b-9, 410b-10, 410b-11, and 410b-12 and is coupled to the gates 410b-9, 410b-10, 410b-11, and 410b-12 by the respective gate contacts 420b-9, 420b-10, 420b-11, and 420b-12 and respective vias (e.g., VG in FIG. 1). Both of the interconnects 634 and 664 are coupled to the input (labeled “A” in FIG. 7C) of the inverter 680 by signal routing formed in one or more metal layers above metal layer M0.

In this example, the layout includes an interconnect 690 coupled to the source/drain 430a-10, the source/drain 430b-12, the source/drain 430b-10, and the source/drain 430b-12. Each of the source/drain 430a-10, the source/drain 430b-12, the source/drain 430b-10, and the source/drain 430b-12 may be coupled to the interconnect 690 by a respective contact (e.g., MD in FIG. 1) and a respective via (e.g., VD in FIG. 1). The interconnect 690 may be formed in metal layer M0 and metal layer M1 (e.g., using a lithographic and etching process) in which the portion of the interconnect 690 formed in metal layer M0 is coupled to the portion of the interconnect 690 formed in metal layer M1 by one of more vias (e.g., V0 in FIG. 1). The interconnect 690 may be coupled to the output of the inverter 680.

The source/drain 430a-9, the source/drain 430a-11, and the source/drain 430a-13 are coupled to the supply rail by respective contacts (e.g., MD in FIG. 1) and vias (e.g., VD in FIG. 1), and the source/drain 430b-9, source/drain 430b-11, the source/drain 430b-13 are coupled to the low rail by respective contacts (e.g., MD in FIG. 1) and vias (e.g., VD in FIG. 1).

In this example, the source/drain 430a-9, the gate 410a-9, and the source/drain 430a-10 provide the source, the gate, and the drain, respectively, of the first PFET 752. The source/drain 430a-11, the gate 410a-10, and the source/drain 430a-10 provide the source, the gate, and the drain, respectively, of the second PFET 754. The source/drain 430a-13, the gate 410a-12, and the source/drain 430a-12 provide the source, the gate, and the drain, respectively, of the third PFET 756. The source/drain 430a-11, the gate 410a-11, and the source/drain 430a-12 provide the source, the gate, and the drain, respectively, of the fourth PFET 758.

Also, the source/drain 430b-10, the gate 410b-9, and the source/drain 430b-9 provide the drain, the gate, and the source, respectively, of the first NFET 762. The source/drain 430b-10, the gate 410b-10, and the source/drain 430b-11 provide the drain, the gate, and the source, respectively, of the second NFET 764. The source/drain 430b-12, the gate 410b-12, and the source/drain 430b-13 provide the drain, the gate, and the source, respectively, of the third NFET 766. The source/drain 430b-12, the gate 410b-11, and the source/drain 430b-11 provide the drain, the gate, and the source, respectively, of the fourth NFET 768.

In this example, the source/drain 430a-9 and the source/drain 430b-9 are shared by the inverter 680 and the NOR gate 615. This allows each of the diffusion regions 412a and 412b to be contiguous (i.e., continuous) across the inverter 680 and the NOR gate 615 with no diffusion breaks separating the inverter 680 and the NOR gate 615. The inverter 680 and the NOR gate 615 are able to share a source/drain that is coupled to the supply rail or the low rail. In the example shown in FIGS. 6A and 6B, the shared source/drain 430a-9 in the diffusion region 412a (which is p-type in this example) is coupled to the supply rail and the shared source/drain 430b-9 in the diffusion region 412b (which is n-type in this example) is coupled to the low rail (e.g., ground rail).

In this example, the inverter 680 is laid out such that the outermost sources/drains 430a-9 and 430a-13 of the inverter 680 in the diffusion region 412a are coupled to the supply rail and the outermost sources/drains 430b-9 and 430b-13 of the inverter 680 in the diffusion region 412b are coupled to the low rail. This layout allows the inverter 680 to share the source/drain 430a-9 and the source/drain 430b-9 with the NOR gate 615.

The second NAND gate 685 shown in FIG. 6B may be implemented in the same manner as discussed above for the first NAND gate 610 shown in FIG. 6A. In this example, the layout for the second NAND gate 685 includes interconnects 636, 638, 640, 666, 668, 670 corresponding to the interconnects 622, 624, 626, 652, 654, and 656, respectively, shown in FIG. 6A and an interconnect 695 corresponding to the interconnect 645 shown in FIG. 6A.

In some cases, it is desirable to increase the spacing between adjacent interconnects in the x direction to provide more area for signal routing to the interconnects. In these cases, a floating gate (also referred to as a dummy gate) may be placed between the gates of the adjacent interconnects to increase the spacing between the adjacent interconnects in the x direction. As used herein a “floating gate” is a gate that is electrically floating (i.e., not coupled to a supply rail, an input, or a low rail). Gates (e.g., the gates 410a-1 to 410a-16 and 410b-1 to 410b-16) that are coupled to an input (e.g., the first input (labeled “A”) or the second input (labeled “B”)) may also be referred to as active gates.

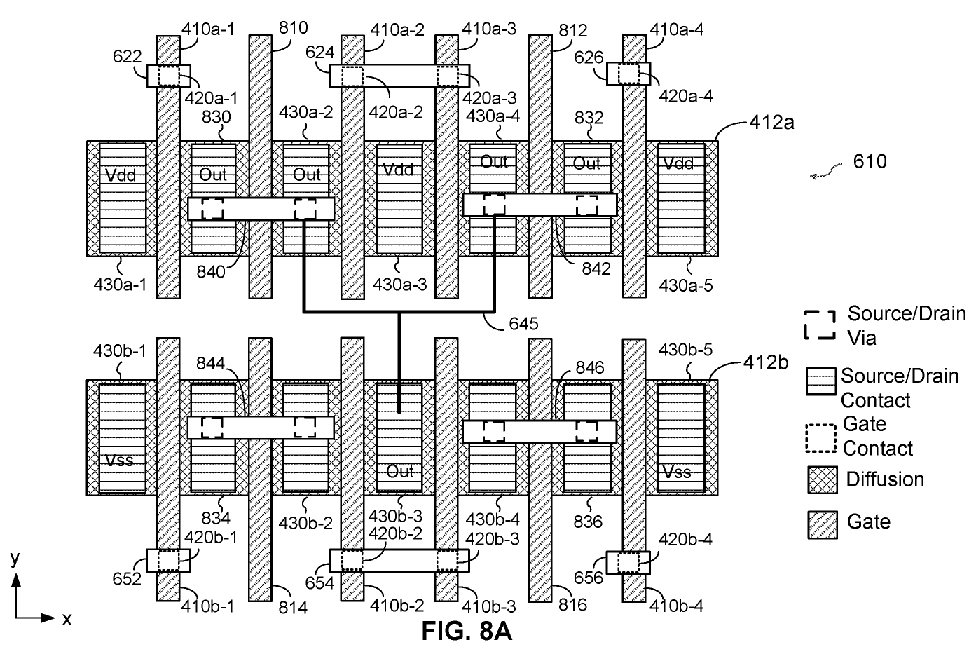

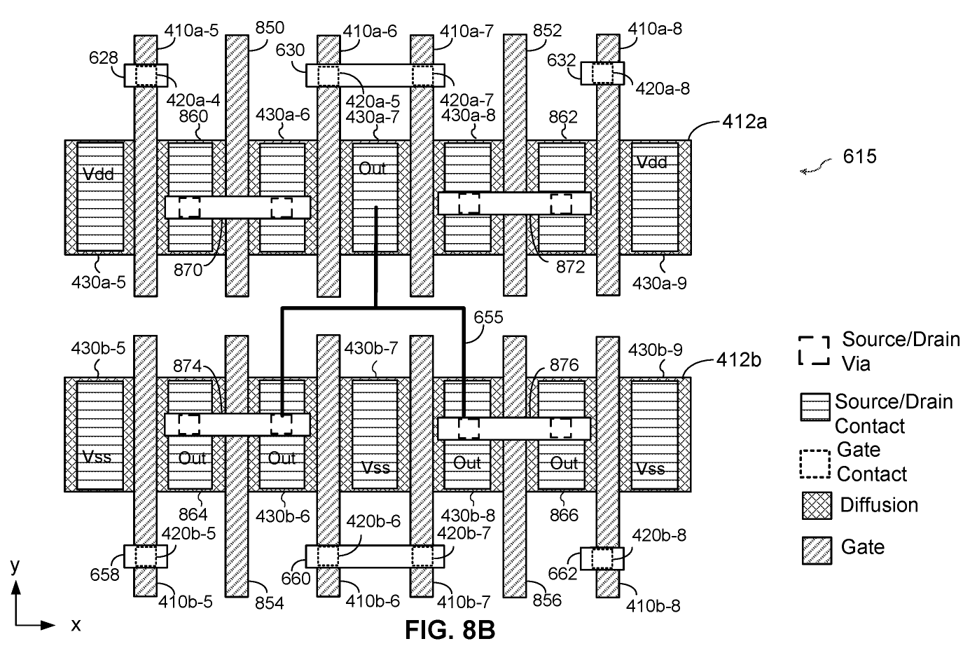

In this regard, FIG. 8A shows a top view of the layout for the first NAND gate 610 in which the layout further includes a first floating gate 810, a second floating gate 812, a third floating gate 814, and a fourth floating gate 816. The first floating gate 810 is disposed between the gates 410a-1 and 410a-2 to increase the spacing between the interconnects 622 and 624, and the second floating gate 812 is disposed between the gates 410a-3 and 410a-4 to increase the spacing between the interconnects 624 and 626. The third floating gate 814 is disposed between the gates 410b-1 and 410b-2 to increase the spacing between the interconnects 652 and 654, and the fourth floating gate 816 is disposed between the gates 410b-3 and 410b-4 to increase the spacing between the interconnects 654 and 656.

In this example, the layout also includes additional sources/drains including source/drain 830 and source/drain 832 in the diffusion region 412a and source/drain 834 and source/drain 836 in diffusion region 412b. The source/drain 830 is between the gate 410a-1 and the first floating gate 810, and the source/drain 430a-2 is between the first floating gate 810 and the gate 410a-2. The source/drain 832 is between the second floating gate 812 and the gate 410a-4, and the source/drain 430a-4 is between the gate 410a-3 and the second floating gate 812. The source/drain 834 is between the gate 410b-1 and the third floating gate 814, and the source/drain 430b-2 is between the third floating gate 814 and the gate 410b-2. The source/drain 836 is between the fourth floating gate 816 and the gate 410b-4, and the source/drain 430b-4 is between the gate 410b-3 and the fourth floating gate 816.

In this example, the layout further includes interconnects 840, 842, 844, and 846. The interconnect 840 extends over the first floating gate 810 and is coupled between the source/drain 830 and the source/drain 430a-2 by contacts (e.g., MD in FIG. 1) and vias (e.g., VD in FIG. 1). The interconnect 840 shorts the source/drain 830 and the source/drain 430a-2. In this example, the source/drain 830 provides the drain of the first PFET 712, and the source/drain 430a-2 provides the drain of the second PFET 714. Both the source/drain 830 and the source/drain 430a-2 are coupled to the interconnect 645, which is coupled to the output of the first NAND gate 610.

The interconnect 842 extends over the second floating gate 812 and is coupled between the source/drain 832 and the source/drain 430a-4 by contacts (e.g., MD in FIG. 1) and vias (e.g., VD in FIG. 1). The interconnect 842 shorts the source/drain 832 and the source/drain 430a-4. In this example, the source/drain 832 provides the drain of the third PFET 716, and the source/drain 430a-4 provides the drain of the fourth PFET 718. Both the source/drain 832 and the source/drain 430a-4 are coupled to the interconnect 645, which is coupled to the output of the first NAND gate 610.

The interconnect 844 extends over the third floating gate 814 and is coupled between the source/drain 834 and the source/drain 430b-2 by contacts (e.g., MD in FIG. 1) and vias (e.g., VD in FIG. 1). The interconnect 844 shorts the source/drain 834 and the source/drain 430b-2. In this example, the source/drain 430b-2 provides the source of the first NFET 722, and the source/drain 834 provides the drain of the second NFET 724.

The interconnect 846 extends over the fourth floating gate 816 and is coupled between the source/drain 836 and the source/drain 430b-4 by contacts (e.g., MD in FIG. 1) and vias (e.g., VD in FIG. 1). The interconnect 846 shorts the source/drain 836 and the source/drain 430b-4. In this example, the source/drain 430b-4 provides the source of the third NFET 726, and the source/drain 836 provides the drain of the fourth NFET 728.

FIG. 8B shows a top view of the layout for the NOR gate 615 in which the layout further includes a first floating gate 850, a second floating gate 852, a third floating gate 854, and a fourth floating gate 856. The first floating gate 850 is disposed between the gates 410a-5 and 410a-6 to increase the spacing between the interconnects 628 and 630, and the second floating gate 852 is disposed between the gates 410a-7 and 410a-8 to increase the spacing between the interconnects 630 and 632. The third floating gate 854 is disposed between the gates 410b-5 and 410b-6 to increase the spacing between the interconnects 658 and 660, and the fourth floating gate 856 is disposed between the gates 410b-7 and 410b-8 to increase the spacing between the interconnects 660 and 662.

In this example, the layout also includes additional sources/drains including source/drain 860 and source/drain 862 in the diffusion region 412a and source/drain 864 and source/drain 866 in diffusion region 412b. The source/drain 860 is between the gate 410a-5 and the first floating gate 850, and the source/drain 430a-6 is between the first floating gate 850 and the gate 410a-6. The source/drain 862 is between the second floating gate 852 and the gate 410a-8, and the source/drain 430a-8 is between the gate 410a-7 and the second floating gate 852. The source/drain 864 is between the gate 410b-5 and the third floating gate 854, and the source/drain 430b-6 is between the third floating gate 854 and the gate 410b-6. The source/drain 866 is between the fourth floating gate 856 and the gate 410b-8, and the source/drain 430b-8 is between the gate 410b-7 and the fourth floating gate 856.

In this example, the layout further includes interconnects 870, 872, 874, and 876. The interconnect 870 extends over the first floating gate 850 and is coupled between the source/drain 860 and the source/drain 430a-6 by contacts (e.g., MD in FIG. 1) and vias (e.g., VD in FIG. 1). The interconnect 870 shorts the source/drain 860 and the source/drain 430a-6. In this example, the source/drain 860 provides the drain of the first PFET 732, and the source/drain 430a-6 provides the source of the second PFET 734.

The interconnect 872 extends over the second floating gate 852 and is coupled between the source/drain 862 and the source/drain 430a-8 by contacts (e.g., MD in FIG. 1) and vias (e.g., VD in FIG. 1). The interconnect 872 shorts the source/drain 862 and the source/drain 430a-8. In this example, the source/drain 862 provides the drain of the third PFET 736, and the source/drain 430a-8 provides the source of the fourth PFET 738.

The interconnect 874 extends over the third floating gate 854 and is coupled between the source/drain 864 and the source/drain 430b-6 by contacts (e.g., MD in FIG. 1) and vias (e.g., VD in FIG. 1). The interconnect 874 shorts the source/drain 864 and the source/drain 430b-6. In this example, the source/drain 864 provides the drain of the first NFET 742, and the source/drain 430b-6 provides the drain of the second NFET 744. Both the source/drain 864 and the source/drain 430b-6 are coupled to the interconnect 655, which is coupled to the output of the NOR gate 615.

The interconnect 876 extends over the fourth floating gate 856 and is coupled between the source/drain 866 and the source/drain 430b-8 by contacts (e.g., MD in FIG. 1) and vias (e.g., VD in FIG. 1). The interconnect 876 shorts the source/drain 866 and the source/drain 430b-8. In this example, the source/drain 866 provides the drain of the third NFET 746, and the source/drain 430b-8 provides the drain of the fourth NFET 748. Both the source/drain 866 and the source/drain 430b-8 are coupled to the interconnect 655, which is coupled to the output of the NOR gate 615.

Implementation examples are described in the following numbered clauses:

1. A chip, comprising:

first gates extending in a first direction, wherein the first gates are spaced apart in a second direction perpendicular to the first direction;

a first diffusion region extending in the second direction, wherein the first diffusion region comprises first bridge channels, and each of the first bridge channels passes through a respective one of the first gates;

first gate contacts, wherein each of the first gate contacts is disposed on a respective one of the first gates, and the first gate contacts are located on one side of the first diffusion region;

second gates extending in the first direction, wherein the second gates are spaced apart in the second direction, and the second gates are aligned with the first gates in the second direction;

a second diffusion region extending in the second direction, wherein the second diffusion region comprises second bridge channels, and each of the second bridge channels passes through a respective one of the second gates; and

second gate contacts, wherein each of the second gate contacts is disposed on a respective one of the second gates, and the second gate contacts are located on one side of the second diffusion region.

2. The chip of clause 1, wherein each of the first bridge channels comprises a respective multi-bridge channel (MBC) and each of the second bridge channels comprises a respective MBC.

3. The chip of clause 1 or 2, wherein the first gates extend across the first diffusion region and do not extend across another diffusion region.

4. The chip of any one of clauses 1 to 3, wherein the first diffusion region comprises first sources/drains separated by the first gates, and the second diffusion region comprises second sources/drains separated by the second gates.

5. The chip of clause 4, wherein each of the first bridge channels is coupled between a respective pair of the first sources/drains, and each of the second bridge channels is coupled between a respective pair of the second sources/drains.

6. The chip of clause 4 or 5, further comprising an interconnect coupled to one or more of the first sources/drains and one or more of the second sources/drains.

7. The chip of clause 6, wherein the first diffusion region and the second diffusion region do not share a gate.

8. The chip of clause 6 or 7, wherein a first one of the first gate contacts and a second one of the first gate contacts are coupled to a first input, and a third one of the first gate contacts and a fourth one of the first gate contacts are coupled to a second input.

9. The chip of clause 8, wherein the first one of the first gate contacts and the second one of the first gate contacts are located between the third one of the first gate contacts and the fourth one of the first gate contacts in the second direction.

10. The chip of clause 8 or 9, wherein a first one of the second gate contacts and a second one of the second gate contacts are coupled to the first input, and a third one of the second gate contacts and a fourth one of the second gate contacts are coupled to the second input.

11. The chip of clause 10, wherein the first one of the second gate contacts and the second one of the second gate contacts are located between the third one of the second gate contacts and the fourth one of the second gate contacts in the second direction.

12. The chip of clause 10 or 11, wherein the first one of the first gate contacts is aligned with the first one of the second gate contacts in the second direction, and the second one of the first gate contacts is aligned with the second one of the second gate contacts in the second direction.

13. The chip of any one of clauses 10 to 12, wherein the first input and the second input provide inputs of a NAND gate and the interconnect provides an output of the NAND gate.

14. The chip of any one of clauses 10 to 12, wherein the first input and the second input provide inputs of a NOR gate and the interconnect provides an output of the NOR gate.

15. The chip of clause 6 or 7, wherein a first one of the first gate contacts, a second one of the first gate contacts, a first one of the second gate contacts, and a second one of the second gate contacts are coupled to an input.

16. The chip of clause 15, wherein the input provides an input of an inverter and the interconnect provides an output of the inverter.

17. The chip of any one of clauses 1 to 16, wherein the first diffusion region is a p-type diffusion region and the second diffusion region is an n-type diffusion region.

18. A chip, comprising:

first gates extending in a first direction, wherein the first gates are spaced apart in a second direction perpendicular to the first direction;

a first diffusion region extending in the second direction, wherein the first gates extend across the first diffusion region, the first gates do not extend across another diffusion region, the first diffusion region comprises first bridge channels, and each of the first bridge channels passes through a respective one of the first gates; and

first gate contacts, wherein each of the first gate contacts is disposed on a respective one of the first gates, and the first gate contacts are located on one side of the first diffusion region.

19. The chip of clause 18, wherein the first gate contacts are located between the first diffusion region and first ends of the first gates, and a first distance between the first diffusion region and the first ends of the first gates is at least two times longer than a second distance between the first diffusion region and second ends of the first gates opposite the first ends of the first gates.

20. The chip of clause 19, wherein the second distance is approximately equal to a minimum diffusion-gate cut distance in design rule checks of a process technology used to fabricate the chip.

21. The chip of any one of clauses 18 to 20, wherein each of the first bridge channels comprises a respective multi-bridge channel (MBC).

22. The chip of any one of clauses 18 to 21, wherein the first diffusion region comprises sources/drains separated by the first gates.

23. The chip of any one of clauses 18 to 22, further comprising:

second gates extending in the first direction, wherein the second gates are spaced apart in the second direction, and the second gates are aligned with the first gates in the second direction;

a second diffusion region extending in the second direction, wherein the second diffusion region comprises second bridge channels, and each of the second bridge channels passes through a respective one of the second gates; and

second gate contacts, wherein each of the second gate contacts is disposed on a respective one of the second gates, and the second gate contacts are located on one side of the second diffusion region.

24. The chip of clause 23, wherein the first diffusion region comprises first sources/drains separated by the first gates, and the second diffusion region comprises second sources/drains separated by the second gates.

25. The chip of clause 24, wherein each of the first bridge channels is coupled between a respective pair of the first sources/drains, and each of the second bridge channels is coupled between a respective pair of the second sources/drains.

26. The chip of clause 24 or 25, further comprising an interconnect coupled to one or more of the first sources/drains and one or more of the second sources/drains.

27. The chip of clause 26, wherein the first diffusion region and the second diffusion region do not share a gate.

28. The chip of clause 26 or 27, wherein a first one of the first gate contacts and a second one of the first gate contacts are coupled to a first input, and a third one of the first gate contacts and a fourth one of the first gate contacts are coupled to a second input.

29. The chip of clause 28, wherein the first one of the first gate contacts and the second one of the first gate contacts are located between the third one of the first gate contacts and the fourth one of the first gate contacts in the second direction.

30. The chip of clause 28 or 29, wherein a first one of the second gate contacts and a second one of the second gate contacts are coupled to the first input, and a third one of the second gate contacts and a fourth one of the second gate contacts are coupled to the second input.

31. The chip of clause 30, wherein the first one of the second gate contacts and the second one of the second gate contacts are located between the third one of the second gate contacts and the fourth one of the second gate contacts in the second direction.

32. The chip of clause 30 or 31, wherein the first one of the first gate contacts is aligned with the first one of the second gate contacts in the second direction, and the second one of the first gate contacts is aligned with the second one of the second gate contacts in the second direction.

33. The chip of any one of clauses 30 to 32, wherein the first input and the second input provide inputs of a NAND gate and the interconnect provides an output of the NAND gate.

34. The chip of any one of clauses 30 to 32, wherein the first input and the second input provide inputs of a NOR gate and the interconnect provides an output of the NOR gate.

35. The chip of clause 26 or 27, wherein a first one of the first gate contacts, a second one of the first gate contacts, a first one of the second gate contacts, and a second one of the second gate contacts are coupled to an input.

36. The chip of clause 35, wherein the input provides an input of an inverter and the interconnect provides an output of the inverter.

37. The chip of any one of clauses 23 to 36, wherein the first diffusion region is a p-type diffusion region and the second diffusion region is an n-type diffusion region.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
first gates extending in a first direction, wherein the first gates are spaced apart in a second direction perpendicular to the first direction;
a first diffusion region extending in the second direction, wherein the first diffusion region comprises first bridge channels, and each of the first bridge channels passes through a respective one of the first gates;
first gate contacts, wherein each of the first gate contacts is disposed on a respective one of the first gates, and the first gate contacts are located on one side of the first diffusion region;
second gates extending in the first direction, wherein the second gates are spaced apart in the second direction, and the second gates are aligned with the first gates in the second direction;
a second diffusion region extending in the second direction, wherein the second diffusion region comprises second bridge channels, and each of the second bridge channels passes through a respective one of the second gates; and
second gate contacts, wherein each of the second gate contacts is disposed on a respective one of the second gates, and the second gate contacts are located on one side of the second diffusion region.

2. The chip of claim 1, wherein each of the first bridge channels comprises a respective multi-bridge channel (MBC) and each of the second bridge channels comprises a respective MBC.

3. The chip of claim 1, wherein the first gates extend across the first diffusion region and do not extend across another diffusion region.

4. The chip of claim 1, wherein the first diffusion region comprises first sources/drains separated by the first gates, and the second diffusion region comprises second sources/drains separated by the second gates.

5. The chip of claim 4, wherein each of the first bridge channels is coupled between a respective pair of the first sources/drains, and each of the second bridge channels is coupled between a respective pair of the second sources/drains.

6. The chip of claim 4, further comprising an interconnect coupled to one or more of the first sources/drains and one or more of the second sources/drains.

7. The chip of claim 6, wherein the first diffusion region and the second diffusion region do not share a gate.

8. The chip of claim 6, wherein a first one of the first gate contacts and a second one of the first gate contacts are coupled to a first input, and a third one of the first gate contacts and a fourth one of the first gate contacts are coupled to a second input.

9. The chip of claim 8, wherein the first one of the first gate contacts and the second one of the first gate contacts are located between the third one of the first gate contacts and the fourth one of the first gate contacts in the second direction.

10. The chip of claim 8, wherein a first one of the second gate contacts and a second one of the second gate contacts are coupled to the first input, and a third one of the second gate contacts and a fourth one of the second gate contacts are coupled to the second input.

11. The chip of claim 10, wherein the first one of the second gate contacts and the second one of the second gate contacts are located between the third one of the second gate contacts and the fourth one of the second gate contacts in the second direction.

12. The chip of claim 10, wherein the first one of the first gate contacts is aligned with the first one of the second gate contacts in the second direction, and the second one of the first gate contacts is aligned with the second one of the second gate contacts in the second direction.

13. The chip of claim 10, wherein the first input and the second input provide inputs of a NAND gate and the interconnect provides an output of the NAND gate.

14. The chip of claim 10, wherein the first input and the second input provide inputs of a NOR gate and the interconnect provides an output of the NOR gate.

15. The chip of claim 6, wherein a first one of the first gate contacts, a second one of the first gate contacts, a first one of the second gate contacts, and a second one of the second gate contacts are coupled to an input.

16. The chip of claim 15, wherein the input provides an input of an inverter and the interconnect provides an output of the inverter.

17. The chip of claim 1, wherein the first diffusion region is a p-type diffusion region and the second diffusion region is an n-type diffusion region.

18. A chip, comprising:
first gates extending in a first direction, wherein the first gates are spaced apart in a second direction perpendicular to the first direction;
a first diffusion region extending in the second direction, wherein the first gates extend across the first diffusion region, the first gates do not extend across another diffusion region, the first diffusion region comprises first bridge channels, and each of the first bridge channels passes through a respective one of the first gates; and
first gate contacts, wherein each of the first gate contacts is disposed on a respective one of the first gates, and the first gate contacts are located on one side of the first diffusion region.

19. The chip of claim 18, wherein the first gate contacts are located between the first diffusion region and first ends of the first gates, and a first distance between the first diffusion region and the first ends of the first gates is at least two times longer than a second distance between the first diffusion region and second ends of the first gates opposite the first ends of the first gates.

20. The chip of claim 19, wherein the second distance is approximately equal to a minimum diffusion-gate cut distance in design rule checks of a process technology used to fabricate the chip.

21. The chip of claim 18, wherein each of the first bridge channels comprises a respective multi-bridge channel (MBC).

22. The chip of claim 18, wherein the first diffusion region comprises sources/drains separated by the first gates.

23. The chip of claim 18, further comprising:
second gates extending in the first direction, wherein the second gates are spaced apart in the second direction, and the second gates are aligned with the first gates in the second direction;
a second diffusion region extending in the second direction, wherein the second diffusion region comprises second bridge channels, and each of the second bridge channels passes through a respective one of the second gates; and
second gate contacts, wherein each of the second gate contacts is disposed on a respective one of the second gates, and the second gate contacts are located on one side of the second diffusion region.

24. The chip of claim 23, wherein the first diffusion region comprises first sources/drains separated by the first gates, and the second diffusion region comprises second sources/drains separated by the second gates.

25. The chip of claim 24, wherein each of the first bridge channels is coupled between a respective pair of the first sources/drains, and each of the second bridge channels is coupled between a respective pair of the second sources/drains.

26. The chip of claim 24, further comprising an interconnect coupled to one or more of the first sources/drains and one or more of the second sources/drains.

27. The chip of claim 26, wherein the first diffusion region and the second diffusion region do not share a gate.

28. The chip of claim 26, wherein a first one of the first gate contacts and a second one of the first gate contacts are coupled to a first input, and a third one of the first gate contacts and a fourth one of the first gate contacts are coupled to a second input.

29. The chip of claim 28, wherein the first one of the first gate contacts and the second one of the first gate contacts are located between the third one of the first gate contacts and the fourth one of the first gate contacts in the second direction.

30. The chip of claim 28, wherein a first one of the second gate contacts and a second one of the second gate contacts are coupled to the first input, and a third one of the second gate contacts and a fourth one of the second gate contacts are coupled to the second input.
